(19) United States
(12) Patent Application Publication
(10) Pub. No.: US 2004/0037057 A1
(43) Pub. Date: Feb. 26, 2004

(54) Radiating structure for electronic circuit units, capable of efficiently radiating heat of heater element

(75) Inventor: Norihito Okada, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/639,385

(22) Filed: Aug. 11, 2003

(30) Foreign Application Priority Data
Aug. 23, 2002 (JP) 2002-243708

(51) Int. Cl. H05K 7/02; H05K 7/06; H05K 7/08; H05K 7/10

(52) U.S. Cl. 361/760

(57) ABSTRACT

A radiating structure of an electronic circuit unit comprising a circuit board, on which a plurality of circuit parts including a heater element are mounted, and a radiating plate of an aluminum material supporting the circuit board, the circuit board and the radiating plate being beforehand fixed together by the eyelets or the like, in which state cream solder is applied on predetermined portions of the circuit board to make reflow solder, thereby filling solder into through-holes provided in the circuit board to bring the circuit board into contact with the radiating plate. When the radiating structure thus constructed is adopted, the solder filled into the through-holes heightens degree of adhesion between the circuit board and the radiating plate, so that heat of the heater element can be efficiently radiated outside through the radiating plate from the circuit board.

### BACKGROUND OF THE INVENTION

1. Field of the Invention

The present invention relates to a radiating structure of an electronic circuit unit comprising a circuit board, on which a heater element is mounted.

2. Background Art

In up-converter units used in, for example, transmitters for TV, circuit parts including a heater element, such as power ICs or the like, are mounted, and so there is a need of taking measures to prevent heat from such heater element from adversely affecting other circuit parts.

Conventionally, known as a radiating structure of such electronic circuit unit is a configuration, in which a circuit board mounting thereon a heater element is stored and fixed in a housing made of a metallic material, such as aluminum or the like, having an excellent thermal conductivity, and heat from the heater element is radiated outside from the circuit board through the housing.

With the conventional radiating structure described above, however, the circuit board is only fixed at a plurality of locations thereof to a bottom surface of the housing by means of screwing or caulking with eyelets, and screwing or caulking with eyelets cannot be specifically applied in a location, in which the heater element is mounted, thus causing a problem that adhesion of the circuit board and the housing is worsened in the vicinity of a heating source and heat from the heater element cannot be efficiently radiated outside from the circuit board through the housing.

### SUMMARY OF THE INVENTION

The invention has been thought of in view of such actual situation in the prior art, and has its object to provide a radiating structure of such electronic circuit unit capable of efficiently radiating heat of a heater element mounted on a circuit board.

To attain the above object, the invention provides a radiating structure of an electronic circuit unit comprising a circuit board, on which a plurality of circuit parts including a heater element are mounted, and a metallic radiating plate supporting the circuit board, and wherein solder is filled into through-holes provided in the circuit board in a state, in which the circuit board and the radiating plate are unified by fixing means.

With the radiating structure constructed in this manner, when the circuit board and the radiating plate are beforehand fixed together by the eyelets or the like, in which state the cream solder is applied on the circuit board to be conveyed into the reflow furnace, the cream solder flows into the through-holes to reach the radiating plate, whereby the solder heightens the degree of adhesion between the circuit board and the radiating plate to enable efficiently radiating heat of the heater element outside through the radiating plate from the circuit board.

With the above constitution, solder lands are preferably provided on a surface of the circuit board opposed to the radiating plate to surround the through-holes. When such constitution is adopted, since solder having flown into the through-holes is dammed up by the solder lands, it is possible to strictly control an amount of the cream solder as applied.

Also, with the above constitution, in the case where the heater element mounted on the circuit board comprises a ground electrode on a bottom surface thereof, the heater element is mounted on the circuit board so that the ground electrode is positioned just above the through-holes, which is preferable in that heat of the heater element can be efficiently radiated further and the ground electrode on the heater element can be connected to the radiating plate through solder in the through-holes.

Also, with the above constitution, while the radiating plate is not specifically limited in shape, an outward form of the radiating plate is rectangular-shaped to be larger than the circuit board to enable both sides of the radiating plate projecting from the circuit board to serve also as a guide, so that when applied to up-converter units used in, for example, transmitters for TV, insertion into and removal from a slot provided in an equipment body of a transmitter can be simply performed with the both sides of the radiating plate as a guide.

In this case, while it is possible to use an iron plate, stainless plate, or the like for the radiating plate, it is preferable to use the radiating plate formed of an aluminum plate having an excellent thermal conductivity.

### BRIEF DESCRIPTION OF THE DRAWINGS

FIG. 1 is a perspective view showing an electronic circuit unit according to an embodiment of the invention;

FIG. 2 is a cross sectional view showing an essential part of a radiating structure of the electronic circuit unit; and

FIG. 3 is a view illustrating a manufacturing process of the electronic circuit unit.

### DESCRIPTION OF THE PREFERRED EMBODIMENTS

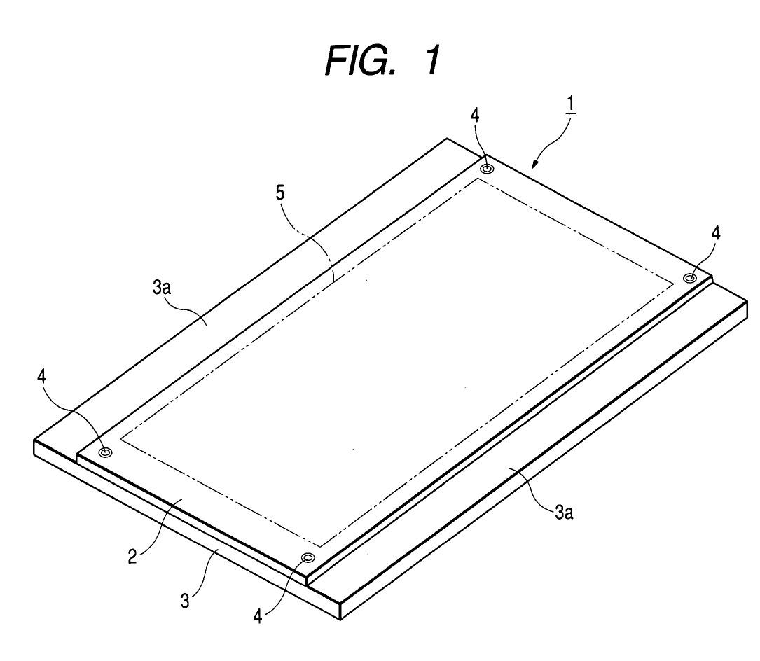

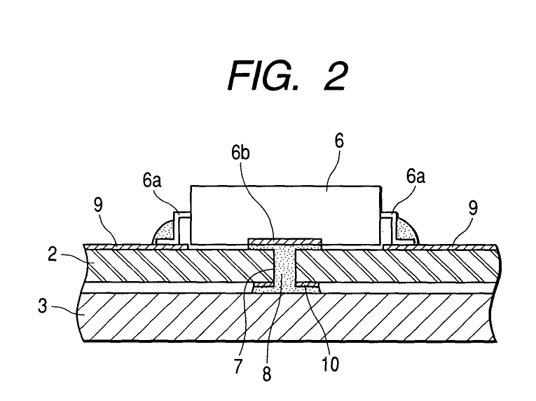

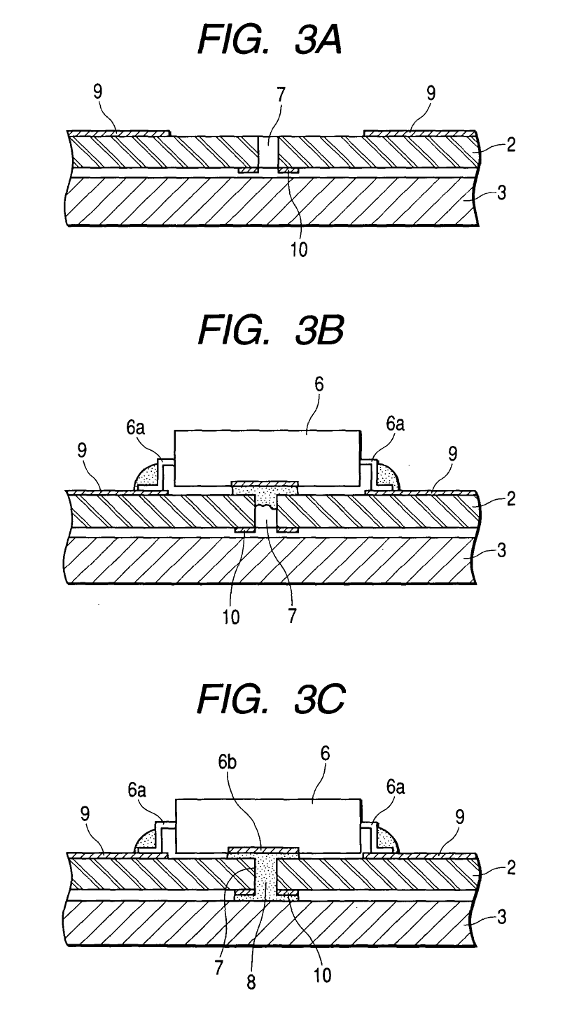

An embodiment of the invention will be described with reference to the drawings. FIG. 1 is a perspective view showing an electronic circuit unit according to an embodiment of the invention, FIG. 2 is a cross sectional view showing an essential part of a radiating structure of the electronic circuit unit, and FIG. 3 is a view illustrating a manufacturing process of the electronic circuit unit.

The electronic circuit unit 1 according to the embodiment is an up-converter unit used in transmitters for TV, and is inserted or removed from a slot provided in an equipment body of a transmitter (not shown).

As shown in FIG. 1, the electronic circuit unit 1 comprises a circuit board 2 formed with an up-converter circuit, and a radiating plate 3 in the form of a flat plate and made of aluminum, the circuit board 2 having its peripheral edge portion fixed to the radiating plate 3 by means of a plurality of eyelets 4 (fixing means). Soldered to the circuit board 2 are a plurality of circuit parts 5 of surface mount type constituting the up-converter circuit, which circuit parts 5 include a heater element 6, such as power ICs or the like, as well as chip capacitors, chip resistors, or the like. The radiating plate 3 is rectangular-shaped to be larger than the circuit board 2, and both sides 3a of the radiating plate 3 extending from the circuit board 2 function as a guide when the electronic circuit unit 1 is inserted into and removed from a slot of the equipment body.

As shown in FIG. 2, a plurality of through-holes 7 are formed on the circuit board 2 to extend vertically through the same, and solder bodies 8 are filled in the through-holes 7. Also, a conductive pattern 9 is formed on a surface of the circuit board 2, on a back surface of which are formed solder lands 10 to surround the through-holes 7. Meanwhile, the heater element 6 comprises a plurality of external electrodes 6a on sides thereof, the external electrodes 6a being soldered to lands of the conductive pattern 9 formed on the surface of the circuit board 2. Also, the heater element 6 comprises a ground electrode 6b on a bottom surface thereof, the ground electrode 6b being positioned just above the through-holes 7 to be soldered as at 8.

An explanation will be given to the manufacturing process of the electronic circuit unit 1 thus constituted with reference to FIG. 3. First, as shown in FIG. 3A, the plurality of eyelets 4 are used to fixedly caulk and unify the circuit board 2 and the radiating plate 3. Subsequently, as shown in FIG. 3B, cream solder is applied on the through-holes 7 of the circuit board 2 and the lands of the conductive pattern 9, and the respective circuit parts 5 including the heater element 6 are placed in predetermined positions on the circuit board 2, in which case the circuit board 2 and the radiating plate 3 are then conveyed into a reflow furnace (not shown) to melt and solidify the cream solder. The reflow solder causes the respective circuit parts 5 to be soldered to desired lands of the conductive pattern 9, and the cream solder flows into the through-holes 7 to reach the radiating plate 3 as shown in FIG. 3C, so that the solder bodies 8 filled into the through-holes 7 surely adhere the circuit board 2 and the radiating plate 3 closely to each other. At this time, since the solder bodies 8 having flown into the through-holes 7 are dammed up by the solder lands 10 on the back surface of the circuit board 2, it is possible to strictly control an amount of the cream solder as applied.

With the embodiment, the circuit board 2 and the radiating plate 3 are beforehand fixed together by the eyelets 4 or the like, in which state the cream solder is applied in predetermined locations on the circuit board 2 to perform reflow soldering, whereby the solder bodies 8 are filled into the through-holes 7 to contact with the radiating plate 3, so that the solder bodies 8 heightens the degree of adhesion between the circuit board 2 and the radiating plate 3 to enable efficiently radiating heat of the heater element 6 outside through the radiating plate 3 from the circuit board 2. Also, since a surface (back surface) of the circuit board 2 facing the radiating plate 3 is formed with the solder lands 10, which surround the through-holes 7, the solder bodies 8 having flown into the through-holes 7 are dammed up by the solder lands 10, and so it is possible to strictly control an amount of the cream solder as applied. Further, since the heater element 6 is mounted just above the through-holes 7 and the ground electrode 6b provided on the bottom surface of the heater element 6 is connected to the solder bodies 8, it is possible to efficiently transfer heat of the heater element 6 to the radiating plate 3 from the solder bodies 8 to further heighten the radiating effect and to ground-connect the heater element 6 to the radiating plate 3 through the solder bodies 8.

In addition, while the embodiment has been described with respect to the case where an aluminum material is used for the radiating plate 3, other metallic materials than aluminum can be used. In particular, in the case where an iron plate processed by nickel plating or the like is used for the radiating plate 3, the solder bodies 8 filled into the through-holes 7 are soldered to the radiating plate 3 whereby the mechanical strength of connection between the circuit board 2 and the radiating plate 3 can be increased.

Also, while the embodiment has been described with respect to the case where the radiating structure according to the invention is applied to an up-converter unit used in transmitters for TV, it goes without saying that the radiating structure is applicable to other electronic circuit units than the up-converter unit.

The invention is embodied in the form described above to produce an effect described below.

The circuit board and the radiating plate are beforehand fixed together by the eyelets or the like, in which state the cream solder is applied on the circuit board to be conveyed into the reflow furnace to thereby flow into the through-holes to reach the radiating plate, whereby the solder filled into the through-holes heightens the degree of adhesion between the circuit board and the radiating plate to enable efficiently radiating heat of the heater element outside through the radiating plate from the circuit board.

What is claimed is:

1. A radiating structure of an electronic circuit unit comprising a circuit board, on which a plurality of circuit parts including a heater element are mounted, and a metallic radiating plate supporting the circuit board, and wherein solder is filled into through-holes provided in the circuit board in a state, in which the circuit board and the radiating plate are unified by fixing means.

2. The radiating structure of an electronic circuit unit according to claim 1, wherein solder lands are provided on a surface of the circuit board opposed to the radiating plate to surround the through-holes.

3. The radiating structure of an electronic circuit unit according to claim 1, wherein the heater element comprises a ground electrode on a bottom surface thereof, and the heater element is mounted on the circuit board so that the ground electrode is positioned just above the through-holes.

4. The radiating structure of an electronic circuit unit according to claim 1, wherein an outward form of the radiating plate is rectangular-shaped to be larger than the circuit board.

5. The radiating structure of an electronic circuit unit according to claim 4, wherein the radiating plate is formed of an aluminum plate.
